(19) United States
(12) Patent Application Publication
(10) Pub. No.: US 2011/0250366 A1
(43) Pub. Date: Oct. 13, 2011

(54) BELL JAR FOR SIEMENS REACTOR INCLUDING THERMAL RADIATION SHIELD

(75) Inventors: Gianluca Pazzaglia, Merano (IT); Matteo Fumagalli, Merano (IT); Milind Kulkarni, St. Louis, MO (US)

(73) Assignee: MEMC ELECTRONIC MATERIALS, S.P.A., Novara (IT)

(21) Appl. No.: 13/084,243

(22) Filed: Apr. 11, 2011

(30) Foreign Application Priority Data
Apr. 12, 2010 (IT) TO2010A000278

(51) Int. Cl. C23C 16/02; B23P 11/00; B05D 3/06

(52) U.S. Cl. 427/551; 118/725; 29/428

(57) ABSTRACT

A bell jar for a Siemens reactor of the type used to deposit polycrystalline silicon on a plurality of heated silicon rods via chemical vapor deposition process. The bell jar includes a thermally conductive inner wall having an interior surface at least partially defining an interior space adapted to receive the plurality of heated silicon rods therein. A thermal radiation shield is in the interior space generally adjacent to and in opposing relationship with the interior surface of the inner wall. The thermal radiation shield is substantially opaque to thermal radiation emitted from the plurality of heated silicon rods in the interior space of the bell jar.

### BACKGROUND

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

Highly pure polycrystalline silicon (polysilicon) is a starting material for the fabrication of electronic components and solar cells. It is obtained by thermal decomposition or reduction, with hydrogen, of a silicon source gas. This process is known to those skilled in the art as chemical vapor deposition (CVD). Polysilicon can be produced in so-called Siemens reactors. The chemical vapor deposition of elemental silicon in these CVD reactors takes place on silicon rods, so-called thin rods. The rods are placed in a metal bell jar of the Siemens reactor and are connected electrically to a source of electrical current. These rods are heated to more than 1000° C. through resistive heating when electric current is supplied to the rods. Reaction gas comprising hydrogen and a silicon source gas, for example trichlorosilane, is introduced into the bell jar. The gas mixture is heated by conductive heat transfer when it contacts the surfaces of the rods so that the CVD reaction takes place on the surfaces of silicon rods.

A majority of the electrical energy that is converted to thermal energy at the rods is radiated from the surfaces of the rods due to the high temperatures of the rods. Some of the thermal radiation from each rod becomes incident upon adjacent rods and is absorbed by the rods, thereby contributing to the heating of the rods. The reaction gas is transparent to the thermal radiation, and therefore, the energy of the thermal radiation is not transferred to the reaction gas. Instead, a majority of the thermal radiation reaches the metal wall of the bell jar of the Siemens reactor. The metal wall at least partially absorbs the incident thermal radiation. Heat at the metal wall is transferred by convection to liquid flowing through cooling channels surrounding the metal wall. Transferring heat from the metal wall prevents corrosion of the wall, mechanically stabilizes the wall under pressure, and inhibits silicon deposits on the wall.

### BRIEF DESCRIPTION

In one aspect, a bell jar for a Siemens reactor of the type used to deposit polycrystalline silicon on a plurality of heated silicon rods via chemical vapor deposition process generally comprises a thermally conductive inner wall having an interior surface at least partially defining an interior space adapted to receive the plurality of heated silicon rods therein. A thermal radiation shield in the interior space is generally adjacent to and in opposing relationship with the interior surface of the inner wall. The thermal radiation shield is substantially opaque to thermal radiation emitted from the plurality of heated silicon rods in the interior space of the bell jar.

In another aspect, a method of constructing a radiation shield in a bell jar for a Siemens reactor of the type used to deposit polycrystalline silicon on a plurality of heated silicon rods via chemical vapor deposition process generally comprises providing a plurality of mounting members in at least one row around an interior surface of an inner wall of the bell jar. The interior surface of the inner wall at least partially defines an interior space of the bell jar that is adapted to receive the plurality of heated silicon rods. A plurality of thermal radiation shield members are mounted on the mounting members so that the thermal radiation shield members are arranged side-by-side with respect to one another around the interior surface of the inner wall of the bell jar. The thermal radiation shield members are substantially opaque to thermal radiation emitted from the plurality of heated silicon rods in the interior space of the bell jar during the chemical vapor deposition process.

In yet another aspect, a method of reducing heat loss in a Siemens reactor due to thermal radiation emitted by heated silicon rods in an interior space of a bell jar of the Siemens reactor generally comprises supplying electrical energy to the silicon rods disposed in the interior space of the bell jar of the Siemens reactor. The silicon rods convert the electrical energy into thermal energy, whereby the silicon rods emit thermal radiation. The thermal radiation emitted from the silicon rods is reflected and absorbed using a thermal radiation shield in the interior space of the bell jar. The thermal radiation shield is secured in opposing relationship to the inner wall of the bell jar. The thermal radiation shield is substantially opaque to the thermal radiation emitted from the silicon rods.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a front elevational view of an embodiment of a modified bell jar for a Siemens reactor;

FIG. 2 is a longitudinal section of the modified bell jar taken along the line 2-2 in FIG. 1;

FIG. 3 is an enlarged fragmentary view of the longitudinal section of FIG. 2, with shield members removed from the bell jar;

FIG. 4 is an enlarged fragmentary view of the longitudinal section of FIG. 2;

FIG. 5 is an enlarged fragmentary view of FIG. 3 illustrating a hanger secured to an inner wall of the bell jar;

FIG. 6 is a front plan view of a thermal radiation shield member of the bell jar; and

FIG. 7 is an end elevation view of the thermal radiation shield in FIG. 5.

### DETAILED DESCRIPTION

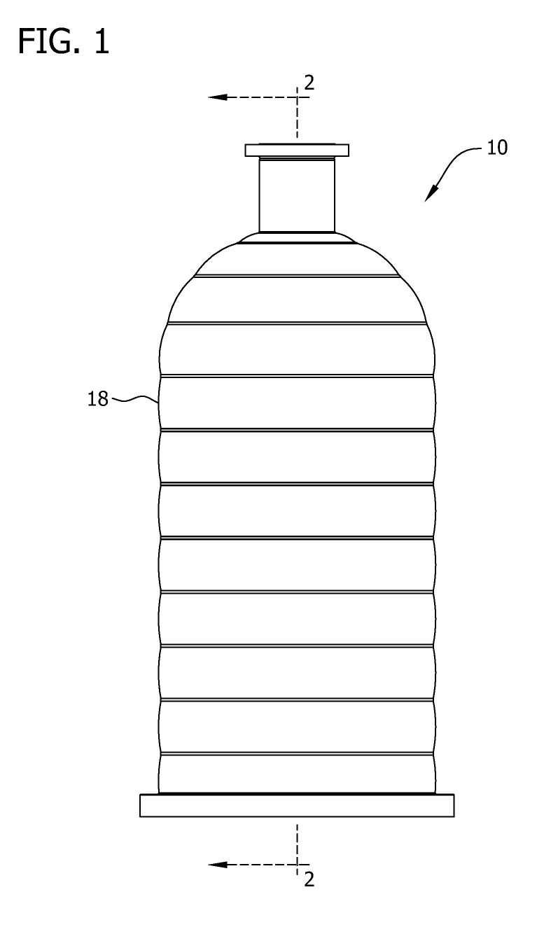

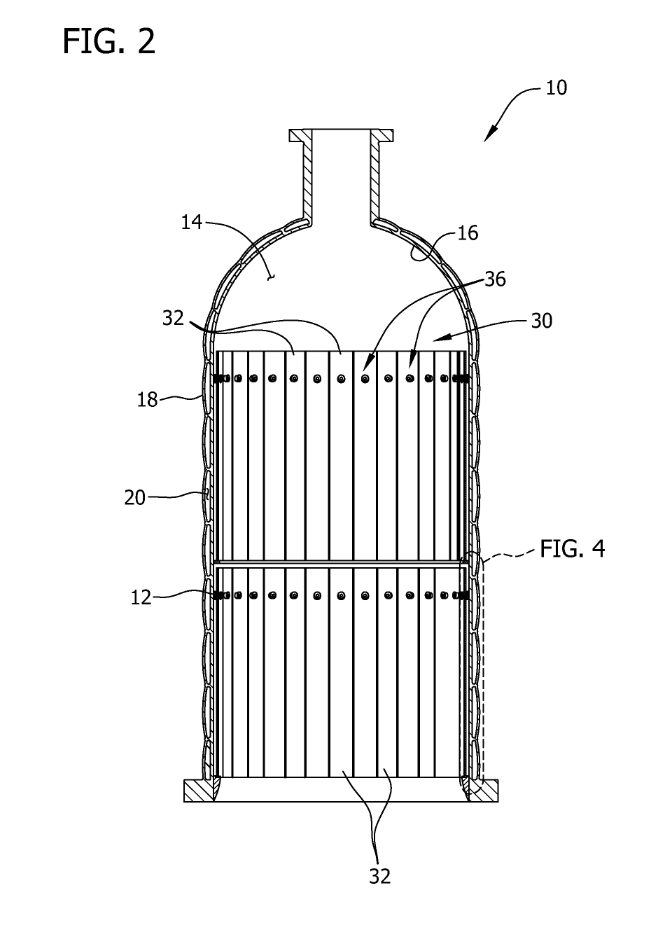

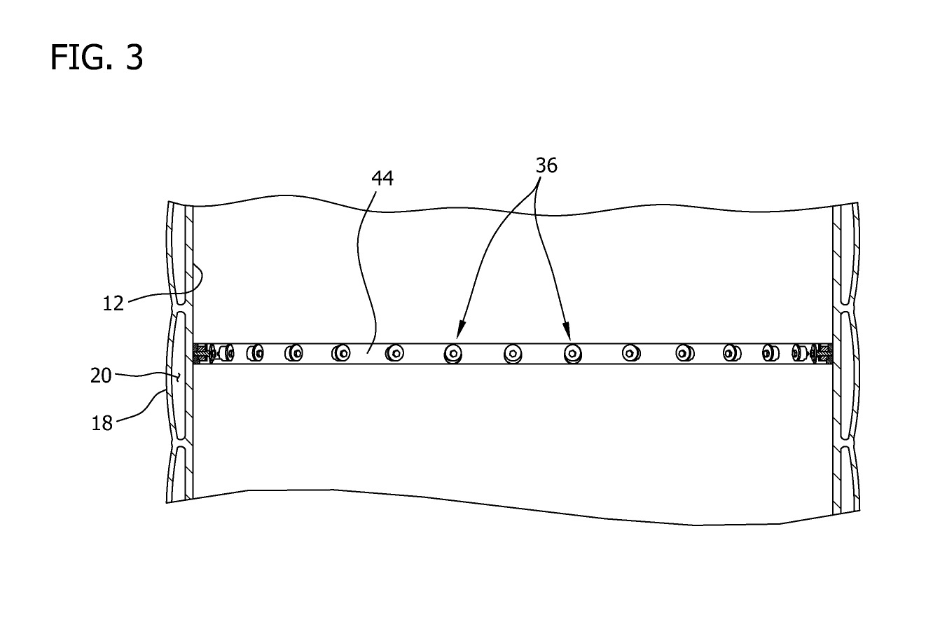

Referring now to the drawings, and in particular to FIGS. 1-3, one embodiment of a bell jar for a Siemens reactor is generally indicated at 10. As used herein, the term “Siemens reactor” is used broadly to refer to a reactor used in the production of polycrystalline silicon (polysilicon) by chemical vapor deposition (CVD). The term “Siemens reactor” is not limited to any specific reactor model or manufacturer. The bell jar 10 generally comprises a metal inner wall 12 (FIGS. 2 and 3), which is generally cylindrical and thermally conductive. The inner wall 12 has an open bottom and an interior surface partially defining an interior space 14 for receiving a plurality of silicon rods (e.g., up to 12-18 rods, or up to 36 rods, or even up to 54 rods). During operation, the silicon rods (not shown) are mounted on a base plate (not shown) of the reactor and extend upward into the interior space 14. As is generally known in the art, the silicon rods are electrically connected to a source of electrical current (not shown) to heat the silicon rods by resistive heating to a temperature of 1000 C or above.

The bell jar 10 also includes a dome-shaped top 16 (FIG. 2) integrally formed on an upper portion of the inner wall 12, and a cooling jacket 18, at least partially defining a conduit 20, surrounding exterior surfaces of the inner wall 12 and the dome-shaped top 16. Together, the inner wall 12 and the dome-shaped top 16 define the interior space 14. As is generally known in the art, reactant gases, such as silane, chlorosilanes, hydrogen, and hydrogen chloride, used during the CVD process are introduced into the interior space 14 through one or more gas inlets (not shown). Gas that has not deposited on the silicon rods during the CVD process is removed from the interior space via a gas outlet (not shown). The cooling jacket 18 includes one or more inlets (not shown) and one or more outlets (not shown). A source of cooling liquid (not shown) may be fluidly connected to the inlet of the cooling jacket 18 for continuously delivering liquid into the conduit 20. As generally known in the art, the flowing cooling liquid in the conduit 20 is in thermal contact with the inner metal wall 16 so that any incident thermal radiation absorbed by the inner wall is transferred to the cooling liquid by forced convective heat transfer and removed from the reactor without contributing to the CVD process.

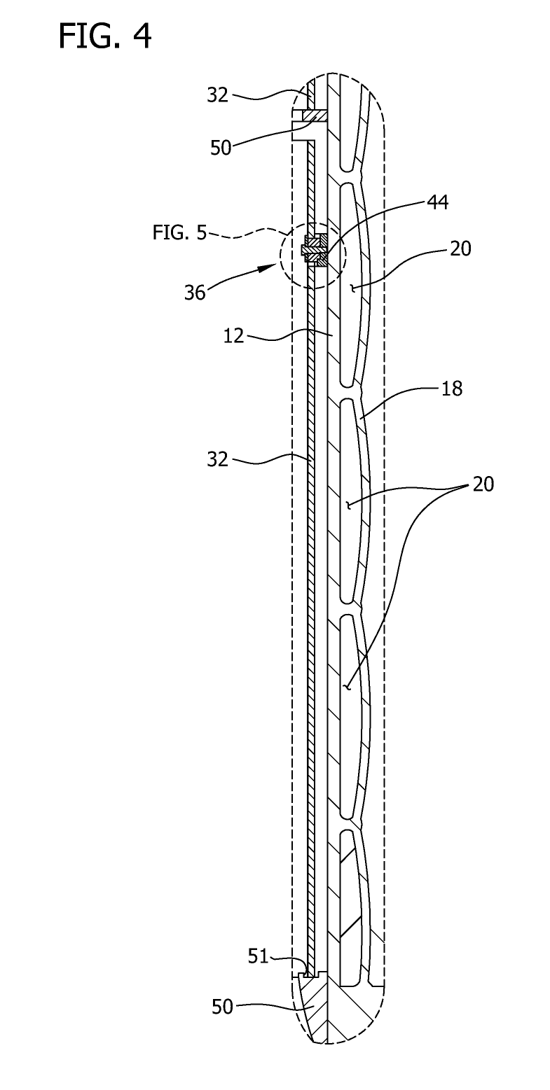

Referring to FIGS. 2-5, the modified bell jar 10 also comprises a thermal radiation shield, generally indicated at 30, in the interior space 14. The thermal radiation shield 30 comprises a plurality of shield members 32 mounted on the inner wall 12. In the illustrated embodiment, the shield members 32 are in the form of generally elongate, thin plates or slabs that are arranged side-by-side in upper and lower rows (FIG. 2). In one embodiment, the shield members 32 may be formed from silicon. It is believed that shield members 32 formed from silicon will not contaminate the silicon rods during the CVD process. Moreover, after using the silicon shield members 32 for several batch cycles, the shield members may be sold as a low grade silicon product after subsequent treatment, such as etching, or the members may be recycled. In one example, the shield members 32 may be cut from quasi-single crystal rods grown through an appropriate process, such as Czochralski growth. In other embodiments, the shield members 32 may be formed from other silicon-containing material, such as silicon oxide, silicon carbide, carbon composite materials coated with silicon carbide. The shield members 32 may also be formed from other material, including material that does not contain silicon, without departing from the scope of the present invention.

Each of the upper and lower rows of shield members 32 span substantially an entire circumference of the inner wall 12 of the bell jar 10, and together, the upper and lower rows span along substantially an entire height of the inner wall from adjacent the open bottom of the bell jar 10 to adjacent the dome-shaped top 16 of the bell jar. The shield 30 opposes or covers at least a majority of the interior surface area of the inner wall 12, and may cover at least about 80% of the interior surface area of the inner wall, and more suitably at least about 88% of the interior surface area of the inner wall and about 67.5% of the combined interior surface of the inner wall and the dome-shaped top 16. The shield 30 may oppose or cover other percentages of the interior surface area of the inner wall 12 without departing from the scope of the present disclosure. Moreover, in other embodiments the shield 30 may also oppose or cover a portion or a majority of the dome-shaped top 16.

In the illustrated embodiment (FIGS. 2-4), the shield members 32 are mounted on hangers, generally indicated at 36 (broadly, mounting members), secured to the interior surface of the inner wall 12. In the illustrated embodiment, each hanger 36 is a two-piece assembly comprising a body member 36a extending toward the center of the interior space 14 from the inner wall 12, and a flange member 36b secured to a terminal end of the body member and projecting upward past an upper surface of the body to define an upper lip 40. In the illustrated embodiment, each hanger 36 is bolted (via bolt 42) to a metal ring 44 that is welded or otherwise secured to the inner wall 12.

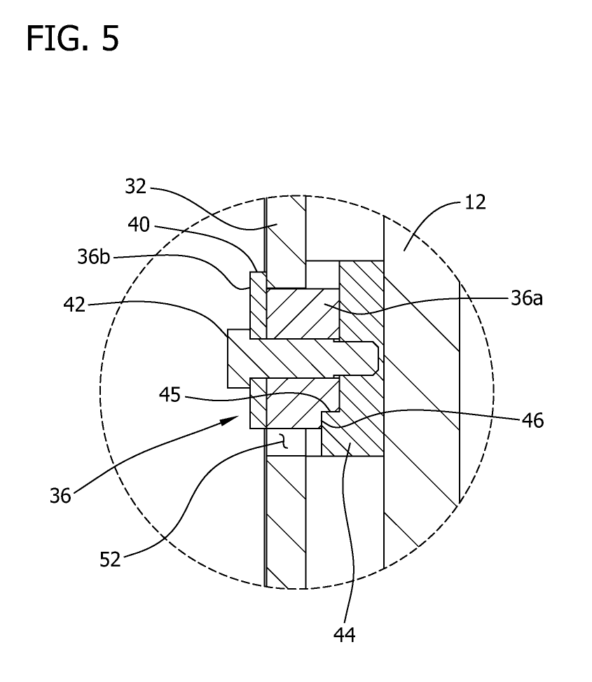

Referring to FIG. 5, each of the illustrated rings 44 includes a ledge 45 that is received in a corresponding groove 46 formed in the body members 36a of the hangers 36 to locate the hangers on the ring and provide additional load-bearing support to the hangers. The hangers 36 may be of other configurations and may be constructed and secured to the inner wall 12 in other ways without departing from the scope of the present disclosure.

Each shield member 32 has an opening 48 in an upper portion thereof that is sized and shaped to receive one of the hangers 36. In particular, the opening 48 is sized and shaped to allow the shield member 32 to be moved over and past the upper lip 40 of the hanger 36. The upper lip 40 acts as a stop that inhibits the shield member 32 from unintentionally slipping off the hanger 36; the shield member 32 must be lifted upward and then moved inward toward the center of the interior space 14 in order to remove the shield member from the hanger 36. With the body member 36a of the hanger 36 received in the opening 48, an upper peripheral margin partially defining the opening 48 rests on the upper surface of the body member.

In the illustrated embodiment, upper and lower rails or platforms 50 are secured, such as by welding, to the inner wall 12 and span circumferentially around the inner wall. Bottoms of the shield members 32 rest on the respective platforms 50 to provide additional support to the shield members and to inhibit the shield members from hitting adjacent shield members when the bell jar 10 is moved, particularly when the bell jar is lifted upward to remove the rods from the reactor. In the illustrated embodiment, the lower platform 50 has a recess or groove 51 in an upper surface thereof in which the bottoms of the shield members are received. Although not shown, the upper platform 50 may also have a groove. Alternatively, both of the platforms may have substantially planar upper surfaces or other contours without departing from the scope of the present invention. In one embodiment, the shield members 32 hang from the respective hangers 36 and rest on the respective platforms 50 so that the shield members are spaced apart from (i.e., are not in contact with) the inner wall 16. In other examples, the bell jar 10 may not include one or more of the platforms 50, and the shield members 32 may thereby hang freely from the hanger 36. For example, the upper platform 50 may be omitted.

As shown best in FIG. 3, when the shield members 32 are hung on the respective hangers 36, a lower peripheral margin partially defining the opening 48 in each shield member is spaced from a lower surface of the corresponding hanger 36. In other words, the dimension of each of the openings 48 is such that there is slack or expansion gap 52 between the body 36a of the hanger 36 and the lower peripheral margin defining the opening. The size of the expansion gap 52 is suitable to allow for longitudinal movement of the shield member 32 relative to the hanger 36 due to thermal expansion during CVD process. Allowing for longitudinal movement of the shield member 32 during thermal expansion inhibits a longitudinal compressive load from acting on the shield member due to the confined, fixed space between the hanger 36 and the platform 50. Also, to inhibit longitudinal compressive loads from acting on the shield members 32 in the lower row, upper portions of the shield members in the lower row may be spaced a suitable distance from the upper platform 50 to inhibit the shield members from pressing against the upper platform during thermal expansion. Moreover, to inhibit lateral compressive loads on the shield members 32, adjacent shield members in each row may be spaced laterally apart from one another a suitable distance to avoid the shield member from pressing against or squeezing laterally adjacent shield members during thermal expansion.

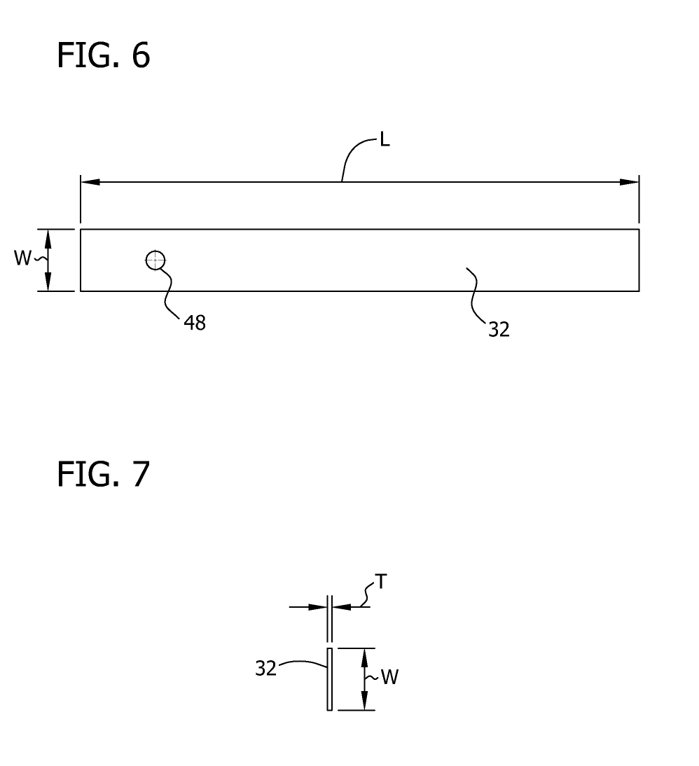

The total number and the dimensions of the shield members 32 and the arrangement of the shield members in the bell jar 10 (e.g., the number of rows, including a single row) are dependent on the size of the bell jar for a particular reactor. In the illustrated embodiment, the bell jar 10 is sized and shaped to process 12-18 silicon rods during a single CVD process. In such a bell jar 10 and as illustrated, the thermal radiation shield 30 may suitably comprise two rows of shield members 32 (i.e., an upper row and a lower row). One example of a bell jar 10 sized and shaped for 12-18 rods may include 32 shield members 32 in each row. Moreover, in such a bell jar 10, each shield member 32 (FIGS. 5 and 6) may have a length L of about 900 mm to about 1100 mm, a width W of about 100 mm to about 200 mm, and a thickness of about 7 mm to about 9 mm. In other embodiments, the shield 30 may suitably include more or fewer rows of heat shield members 32, more or fewer number of shield members, and each of the shield members may be shorter or longer, wider or less wide, and thicker or thinner.

During operation of the reactor, electrical energy from the source of electrical energy is applied to the silicon rods in the interior space 14 of the bell jar 10. The inherent electrical resistance of the silicon rods converts the electrical energy into thermal energy or heat. The thermal energy is transferred by conduction to the reactant gas that contacts the exposed surfaces of the rods, which promotes reactions on the surfaces of the silicon rods to produce polysilicon deposits on the rod surfaces. A majority of the thermal energy is emitted from the surfaces of the rods as thermal radiation. However, because the reactant gases are transparent to the thermal radiation, this thermal energy is not transferred directly to the gases and does not contribute to heating of the gases. The thermal radiation shield 30 is substantially opaque to the thermal radiation and inhibits at least a majority of the thermal radiation emitted from the heated silicon rods, which would otherwise be incident upon the metal inner wall 16, from reaching the inner wall.

In the embodiment where the thermal radiation shield 30 comprises a plurality of silicon shield member 32, it is believed that about 80% of the thermal radiation that is incident upon the shield is absorbed by the shield members. This value is determined by the emissivity of silicon, which is about 0.8 according to literature. The absorbed thermal radiation tends to increase the internal energy of the shield members 32. Thus, the shield members 32 emit thermal radiation, according to their temperatures, in all directions including toward the inner wall 12. However, the shield members 32 are at a much lower temperature than the silicon rods, and therefore, incident thermal radiation from the shield members is less than incident thermal radiation from the silicon rods. Accordingly, less heat must be removed by the cooling jacket 18 as compared to using an unmodified bell jar 10 that does not include the thermal radiation shield 30.

Since silicon is substantially opaque (the coefficient of transmission of silicon is negligible), each of the silicon shield members 32 also reflect about 20% of the incident thermal radiation back toward the silicon rods. This reflected radiation may then be absorbed by the silicon rods to add heat to the rods, which in turn, conduct heat to the reactant gases at the surfaces of the rods.

Based on CFD simulations, the silicon shield 30 may reduce thermal radiation incident on the inner wall 16 by about 30-48% depending on the type of reactor. Without being held to any particular theory, the thermal radiation shield may have a more significant impact on smaller reactors (e.g., 12-18 rod reactors) and less of an impact on larger reactors (e.g., 54 rod reactors) because incident thermal radiation on the shield members 32 is more intense in the smaller reactors. This may be because there are less silicon rods, as compared to the larger reactors, to impede thermal radiation from reaching the shield.

Because the silicon shield 30 reduces incident thermal radiation on the inner wall 16 and reflects and emits thermal radiation back toward the silicon rods, the thermal radiation shield should increase the energy efficiency of the Siemens reactor. Based on CFD simulation, the total energy necessary to complete one CVD process in Siemens reactor including modified bell jar 12 with the thermal radiation shield 30 is decreased by about 20% to about 30% as compared to CVD process using an unmodified bell jar with the Siemens reactor.

This written description uses examples to disclose the invention, including the best mode, and also to enable any person skilled in the art to practice the invention, including making and using any devices or systems and performing any related methods. The patentable scope of the invention may include other examples that occur to those skilled in the art. Such other examples are intended to be within the scope of the invention.

The order of execution or performance of the operations in embodiments of the invention illustrated and described herein is not essential, unless otherwise specified. That is, the operations may be performed in any order, unless otherwise specified, and embodiments of the invention may include additional or fewer operations than those disclosed herein. For example, it is contemplated that executing or performing a particular operation before, contemporaneously with, or after another operation is within the scope of aspects of the invention.

When introducing elements of the present invention or the embodiments thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above constructions without departing from the scope of the invention, it is intended that all matter contained in the above description and shown in the accompanying drawings shall be interpreted as illustrative and not in a limiting sense.

What is claimed is:

1. A bell jar for a Siemens reactor of the type used to deposit polycrystalline silicon on a plurality of heated silicon rods via chemical vapor deposition process, the bell jar comprising:
a thermally conductive inner wall having an interior surface at least partially defining an interior space adapted to receive the plurality of heated silicon rods therein;
a thermal radiation shield in the interior space generally adjacent to and in opposing relationship with the interior surface of the inner wall, wherein the thermal radiation shield is substantially opaque to thermal radiation emitted from the plurality of heated silicon rods in the interior space of the bell jar;
the thermal radiation shield comprising a plurality of shield members; and
a plurality of hangers secured to the interior surface of the inner wall,
wherein the plurality of shield members are removably hung on the hangers.

2. The bell jar set forth in claim 1 wherein each of the shield members includes an opening for receiving the hanger.

3. The bell jar set forth in claim 2 wherein each hanger projects inward into the interior space of the bell jar and includes a lip at a terminal end thereof adapted to inhibit the shield member from slipping off the hanger.

4. The bell jar set forth in claim 2 wherein the opening is sized and shaped to allow for longitudinal movement of the shield member relative to the hanger during thermal expansion of the shield member.

5. The bell jar set forth in claim 4 further comprising a platform secured to the interior surface of the inner wall, the platform adapted to support a bottom of each of the shield members.

6. The bell jar set forth in claim 1 wherein the thermal radiation shields are arranged in at least one row spanning substantially an entire circumference of the interior surface of the inner wall.

7. The bell jar set forth in claim 6 wherein the thermal radiation shields are arranged in at least two vertically spaced apart rows, wherein each row spans substantially an entire circumference of the interior surface of the inner wall and the at least two rows together span substantially an entire height of the interior surface of the inner wall.

8. The bell jar set forth in claim 6 wherein each of the shield members is constructed from silicon.

9. A method of constructing a radiation shield in a bell jar for a Siemens reactor of the type used to deposit polycrystalline silicon on a plurality of heated silicon rods in a chemical vapor deposition process, the method comprising:
providing a plurality of mounting members in at least one row around an interior surface of an inner wall of the bell jar, wherein the interior surface of the inner wall at least partially defines an interior space of the bell jar that is adapted to receive the plurality of heated silicon rods;
mounting a plurality of thermal radiation shield members on the mounting members so that the thermal radiation shield members are arranged side-by-side with respect to one another around the interior surface of the inner wall of the bell jar, wherein the thermal radiation shield members are substantially opaque to thermal radiation emitted from the plurality of heated silicon rods in the interior space of the bell jar during the chemical vapor deposition process.

10. The method set forth in claim 9 wherein the plurality of mounting members comprise a plurality of hangers and wherein the mounting of a plurality of thermal radiation shield members comprises removably hanging the plurality of thermal radiation shields on the hangers.

11. The method set forth in claim 10 wherein each of the shield members has an opening extending therethrough, wherein removably hanging the plurality of thermal radiation shields on the hangers comprises receiving the hangers in the openings of the shield members.

12. The method set forth in claim 9 further comprising:
providing a platform on the interior surface of the inner wall below the plurality of mounting members; and
supporting bottoms of the thermal radiation shield members on the platform when the thermal radiation shield members are mounted on the mounting members.

13. A method of reducing heat loss in a Siemens reactor due to thermal radiation emitted by heated silicon rods in an interior space of a bell jar of the Siemens reactor, the method comprising:
supplying electrical energy to the silicon rods disposed in the interior space of the bell jar of the Siemens reactor, the silicon rods converting the electrical energy into thermal energy, whereby the silicon rods emit thermal radiation;
reflecting and absorbing the thermal radiation emitted from the silicon rods using a thermal radiation shield in the interior space of the bell jar, the thermal radiation shield being secured in opposing relationship to the inner wall of the bell jar, wherein the thermal radiation shield is substantially opaque to the thermal radiation emitted from the silicon rods.

14. The method set forth in claim 13 further comprising reducing incident thermal radiation which would otherwise be incident upon the inner wall by about 30% to about 48%.

15. The method set forth in claim 13 further comprising reducing total electrical energy supplied to the silicon rods by about 20% to about 30% compared to a Siemens reactor not including the thermal radiation shield.
